(19) United States
(12) Patent Application Publication
(10) Pub. No.: US 2004/0190761 A1
(43) Pub. Date: Sep. 30, 2004

(54) Apparatus for fingerprint analysis using current detection

(76) Inventor: Ju-Hyeon Lee, Seoul (KR)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 10/793,645

(22) Filed: Mar. 4, 2004

(30) Foreign Application Priority Data
Mar. 5, 2003 (KR) 10-2003-0013596
Feb. 16, 2004 (KR) 10-2004-0009889

(51) Int. Cl. G06K 9/00; H01L 27/14

(52) U.S. Cl. 382/124; 257/414

(57) ABSTRACT

Disclosed herein is an apparatus for fingerprint recognition. The present invention provides a fingerprint recognition sensor (24). The fingerprint recognition sensor (24) includes a substrate (2), a first electrode layer (4), a semi-insulating layer (6), a second electrode layer (8) and a surface layer (10). The first electrode layer (4) is stacked on the substrate (2) and comprised of a plurality of electrodes to allow a current to flow therethrough. The semi-insulating layer (6) is stacked on the first electrode layer (4) with a certain thickness. The second electrode layer (8) is stacked on the semi-insulating layer (6) and comprised of a plurality of electrodes intersecting the electrodes of the first electrode layer (4) to form a matrix while being spaced apart from each other. The surface layer (10) is stacked on the second electrode layer (8) with a certain thickness.

The present invention is advantageous in that it does not require a lens and an image sensor required for conventional optics-type or contact light emitting element-type fingerprint recognition schemes. It is also effective since it does not cause the problems of static electricity and mechanical impacts, which may occur in conventional semiconductor-type fingerprint recognition schemes.

### RELATED APPLICATIONS

This application claims priority under 35 U.S.C. § 119 or 365 to Korean Application No. 10-2003-0013596, filed Mar. 5, 2003 and Korean Application No. 10-2004-0009889, filed Feb. 16, 2004. The entire teachings of the above applications are incorporated herein by reference.

### BACKGROUND OF THE INVENTION

1. Field of the Invention

The present invention relates, in general, to an apparatus for fingerprint recognition and, more particularly, to an apparatus for fingerprint recognition, in which below the contact surface, a plurality of electrodes form a matrix with which the target to be recognized comes into contact, and the intersecting points of the electrodes forming the matrix constitute pixels, that can reproduce a fingerprint in the form of an image.

2. Description of the Related Art

With the development of economy and society, a method of purchasing and paying for commodities has changed from a direct transaction or cash transaction to a credit card payment transaction or on-line electronic payment transaction. Accordingly, a security problem for personal information has appeared as a social issue. In order to solve the security problem, an Identification (ID) number, a password, etc. are used. However, the ID number, the password, etc. can be easily leaked to another person and illegally used, so that a special care of a user is required.

Further, in order to solve this problem, the necessity of security maintenance using fingerprint recognition apparatuses for detecting and interpreting user's fingerprint arises.

Generally, fingerprint recognition apparatuses are classified into three types: optics-type, semiconductor-type and contact light emitting element-type. For an example of the fingerprint recognition apparatus, a fingerprint recognition sensor for converting a pressure applied to a piezoelectric thin film into an electrical signal to recognize a fingerprint is disclosed in Korean Pat. Publication. No. 2002-0086971.

Further, a fingerprint recognition apparatus using a firefly coef fluorescent material, which emits by an electromotive force due to pressurization, is disclosed in Korean Pat. Publication No. 2002-0062384. Further, a fingerprint recognition apparatus using a contact lighting emitting element is disclosed in Korean Pat. No. 0343065. A fingerprint recognition optical system capable of obtaining the optical axis of an optical system and the verticality of a recognized image is disclosed in Korean Pat. Publication No. 2002-0016084.

However, among the above-described fingerprint recognition apparatuses, the optics-type and contact light emitting element-type fingerprint recognition apparatuses are problematic in that, since they use lenses and image sensors, the volumes thereof are increased compared to that of the semiconductor-type fingerprint recognition apparatus, so that it is difficult to apply the fingerprint recognition apparatuses to portable appliances. The semiconductor-type fingerprint recognition apparatus is also problematic because it is easily damaged by static electricity and mechanical impacts, and it requires expensive production equipment.

In the meantime, a fingerprint recognition apparatus using electrostatic capacitance is disclosed in Japanese Patent Laid-Open Publication No. 4-231803. Another fingerprint recognition apparatus using electrostatic capacitance is disclosed in U.S. Pat. No. 6,462,563 in which the first electrode layer comprised of a plurality of electrodes arranged in a same direction is installed, a second electrode layer comprised of a plurality of electrodes arranged in a direction intersecting the first electrode layer is installed to form a matrix, and then an insulating layer is provided between the first and second electrode layers.

However, the fingerprint recognition apparatuses using electrostatic capacitance are mainly used for a semiconductor-type fingerprint recognition apparatus, and are problematic, since there is a lot of contact resistance between a fingerprint and the surface of a sensor in case of a dry finger, and a high quality fingerprint image cannot be obtained. In addition a dielectric thin film is used for a capacitor, as the fingerprint recognition apparatuses are easily damaged by static electricity. Further, there are problems in that they are easily damaged by mechanical impacts and require expensive production equipment similarly to the semiconductor-type fingerprint recognition apparatus.

### SUMMARY OF THE INVENTION

Accordingly, the present invention has been made keeping in mind the above problems occurring in the prior art, and an object of the present invention is to provide a fingerprint recognition sensor, in which below the contact surface a plurality of electrodes form a matrix with which the target to be recognized comes into contact.

Another object of the present invention is to provide an apparatus for fingerprint recognition, in which the respective intersecting points of the electrodes forming the matrix of the fingerprint recognition sensor constitute pixels, that can reproduce the recognized target in the form of an image.

In accordance with one aspect of the present invention, the above and other objects can be accomplished by the provision of a fingerprint recognition sensor, comprising a substrate(2); a first electrode layer(4) comprised of a plurality of electrodes to allow a current to flow through the top of the substrate(2); a semi-insulating layer(6) stacked on the first electrode layer(4) with a certain thickness; a second electrode layer(8) stacked on the semi-insulating layer(6) and comprised of a plurality of electrodes intersecting the electrodes of the first electrode layer(4) to form a matrix; and a surface layer(10) stacked on the second electrode layer(8) with a certain thickness.

In accordance with another aspect of the present invention, it provides a fingerprint recognition sensor, comprising a substrate(2); a first electrode layer(4) comprised of a plurality of electrodes to allow a current to flow through the top of the substrate(2); a semi-insulating layer(6) stacked on the first electrode layer(4) with a certain thickness; a second electrode layer(8) stacked on the semi-insulating layer(6) and comprised of a plurality of electrodes intersecting the electrodes of the first electrode layer (4) to form a matrix; a surface layer(10) stacked on the second electrode layer(8) with a certain thickness; and an electrode ring(12) formed on one part of the top surface layer to come into contact with a target to be recognized.

In accordance with a further aspect of the present invention, it provides an apparatus for fingerprint recognition, comprising the above fingerprint recognition sensor; a power supply unit(14) connected to the electrodes of the first(4) and second(8) electrode layers of the fingerprint recognition sensor to supply a current thereto; at least one detecting unit(16) connected to the electrodes of the first(4) and second(8) electrode layers to measure signals output from the electrodes of the first(4) and second electrode layers(8); and an image reproducing unit(18) connected to the detecting unit(16) to analyze signal information output from the detecting unit(16) and then reproduce the recognized target in the form of an image.

In accordance with still another aspect of the present invention, it provides an apparatus for fingerprint recognition, comprising the above fingerprint recognition sensor; a power supply unit(14) connected to both the electrode ring(12) and the electrodes of the first electrode layer(4) of the fingerprint recognition sensor to supply a current thereto; at least one detecting unit(16) connected to the electrodes of the first(4) and second electrode layers(8) to measure signals output from the electrodes of the first(4) and second electrode layers(8); and an image reproducing unit(18) connected to the detecting unit(16) to analyze signal information output from the detecting unit(16) and then reproduce the recognized target in the form of an image.

In this case, the fingerprint recognition sensor of the present invention is included in the fingerprint recognition apparatus and constructed to come into contact with the target to be recognized, such as a fingerprint, and to output an electrical signal to the target with the aid of the supply of additional electricity. At this time, the fingerprint recognition sensor is not necessarily equipped with electrical components, but it provides a contact surface for the target to be recognized, and outputs an electrical signal to the target on the contact surface if the fingerprint recognition sensor is constructed as the fingerprint recognition apparatus capable of providing electricity thereto.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view showing a fingerprint recognition apparatus according to the embodiment of the present invention;

FIG. 2 is another aspect of perspective view showing a fingerprint recognition apparatus according to the embodiment of the present invention;

FIG. 3 is a decomposed perspective view of the fingerprint recognition apparatus according to the embodiment of the present invention;

FIG. 4 is another aspect of a decomposed perspective view of the fingerprint recognition apparatus according to the embodiment of the present invention;

FIG. 5 is a cross-sectional view of the fingerprint recognition apparatus according to the embodiment of the present invention;

FIG. 6 is another aspect of a cross-sectional view of the fingerprint recognition apparatus according to the embodiment of the present invention;

FIG. 7 is a top plan view of the fingerprint recognition apparatus according to the embodiment of the present invention; and

FIG. 8 is another aspect of a top plan view of the fingerprint recognition apparatus according to the embodiment of the present invention.

### DETAILED DESCRIPTION OF THE INVENTION

Hereinafter, embodiments of the present invention will be described in detail with reference to the attached drawings.

Reference now should be made to the drawings, in which the same reference numerals are used throughout the different drawings to designate the same or similar components.

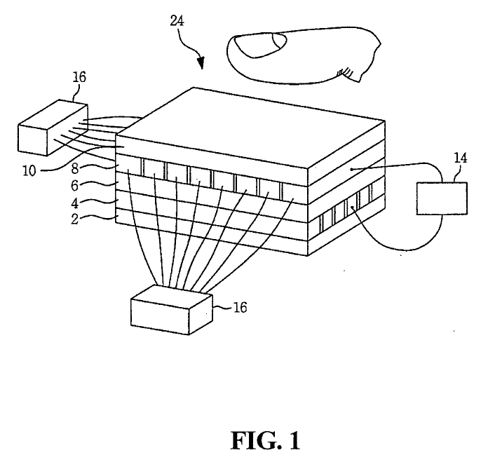

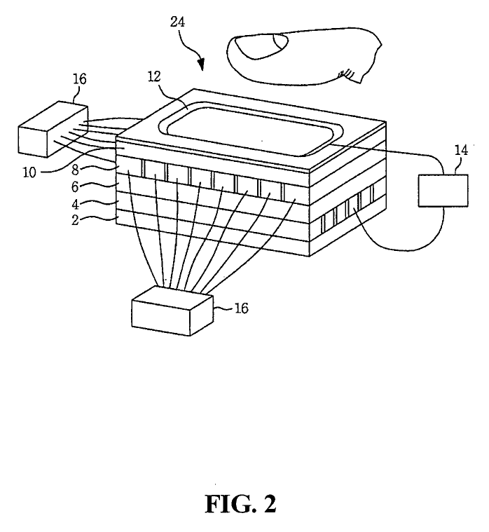

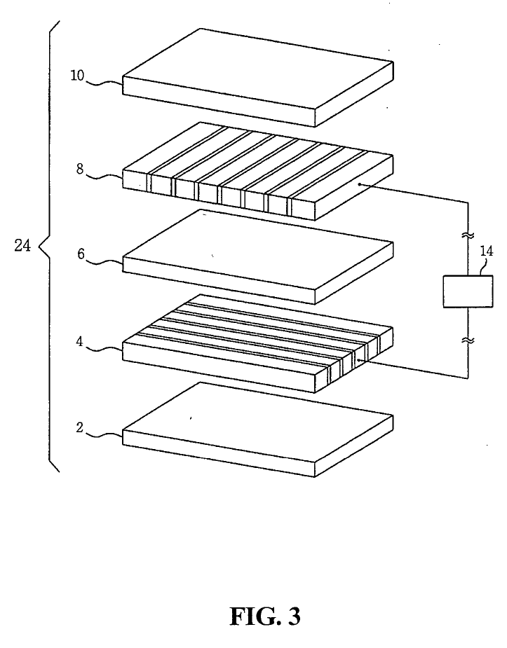

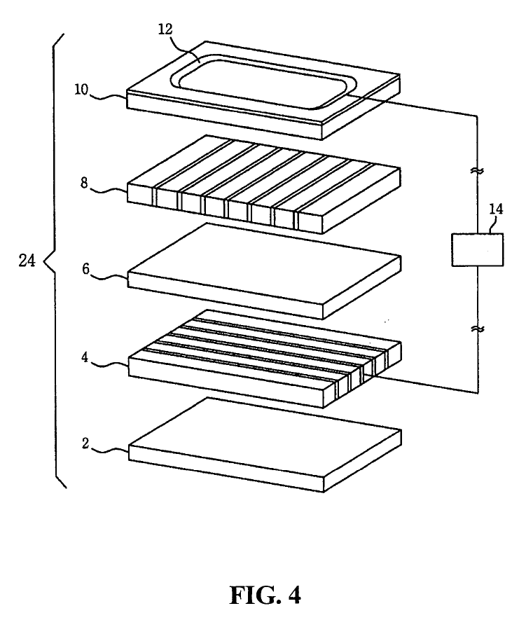

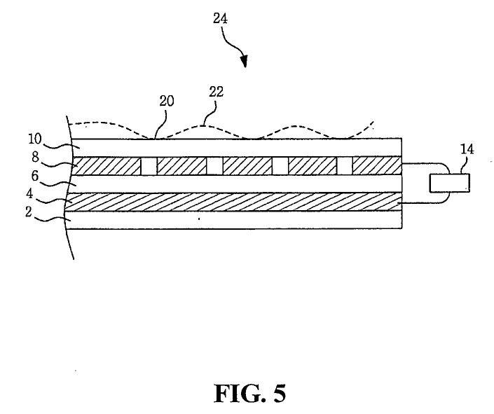

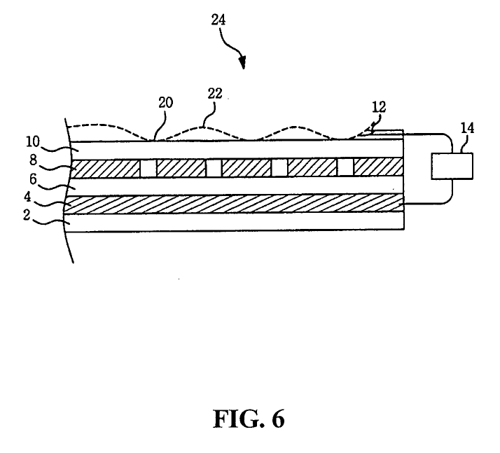

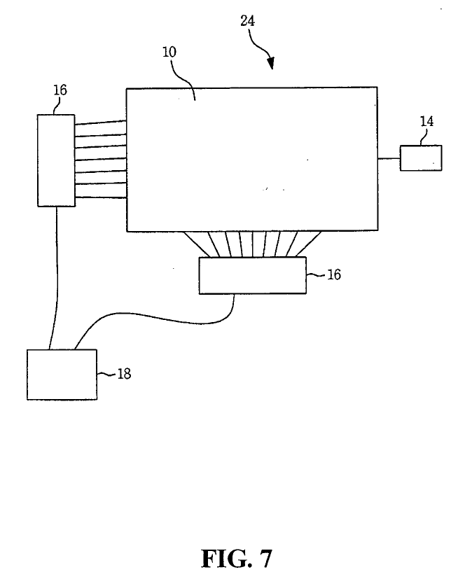

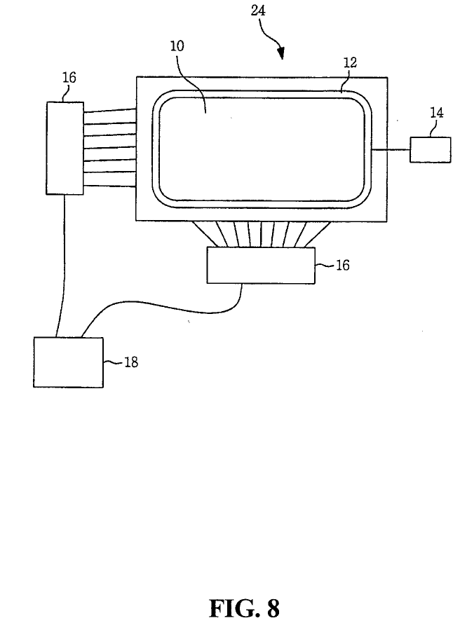

FIG. 1 is a perspective view showing a fingerprint recognition apparatus according to the embodiment of the present invention, FIG. 2 is another aspect of a perspective view showing a fingerprint recognition apparatus according to the embodiment of the present invention, FIG. 3 is a decomposed perspective view of the fingerprint recognition apparatus according to the embodiment of the present invention, FIG. 4 is another aspect of a decomposed perspective view of the fingerprint recognition apparatus according to the embodiment of the present invention, FIG. 5 is a cross-sectional view of the fingerprint recognition apparatus according to the embodiment of the present invention, FIG. 6 is another aspect of a cross-sectional view of the fingerprint recognition apparatus according to the embodiment of the present invention, FIG. 7 is a top plan view of the fingerprint recognition apparatus according to the embodiment of the present invention, and FIG. 8 is another aspect of a top plan view of the fingerprint recognition apparatus according to the embodiment of the present invention.

As shown in FIGS. 1 to 8, the fingerprint recognition apparatus of the present invention includes a fingerprint recognition sensor 24, which comes into contact with a target to be recognized and is capable of outputting an electrical signal to the target to be recognized, a power supply unit 14 connected to the fingerprint recognition sensor 24 to supply a current to the fingerprint recognition sensor 24, detecting units 16 connected to the part of the fingerprint recognition sensor 24 to receive the output signals of the fingerprint recognition sensor 24, and an image reproducing unit 18 connected to the detecting units 16 to reproduce an image on the basis of the received output signals.

In this case, the fingerprint recognition sensor 24 includes a substrate 2, a first electrode layer 4 stacked on the substrate 2 and comprised of a plurality of electrodes to allow a current to flow therethrough, a semi-insulating layer 6 stacked on the first electrode layer 4 with a certain thickness, a second electrode layer 8 stacked on the semi-insulating layer 6 and comprised of a plurality of electrodes intersecting the electrodes of the first electrode layer 4 to form a matrix while being spaced apart from each other, and a surface layer 10 stacked on the second electrode layer 8 with a certain thickness.

If necessary, the fingerprint recognition sensor 24 may further include an electrode ring 12 formed on the part of the top surface layer 10 to come into contact with the target to be recognized.

The fingerprint recognition apparatus of the present invention having the above construction is described in detail as follows.

First, the first electrode layer 4 comprised of the plurality of electrodes formed in parallel with each other to allow a current to flow therethough, is placed on the substrate 2. The semi-insulating layer 6 is stacked on the first electrode layer 4 with a certain thickness.

The above semi-insulating layer 6 is referred to a film that is formed by mixing insulating powder with a polymer binder. For the insulating powder, BaTiO₃, SrTiO₃, CaTiO₃, (Pb, Zr)TiO₃, (Pb, La, Zr)TiO₃ or the mixture thereof can be used, but, most preferably, BaTiO₃ can be used. For materials capable of being used for the polymer binder, any polymer binder typically used in the art, for example, derivatives-based polymer, such as Polyvinyl Alcohol (PVA), can be used.

The second electrode layer 8 comprised of the plurality of electrodes, which are formed in parallel with each other and arranged to intersect the electrodes of the first electrode layer 4, preferably, to be orthogonal while being spaced apart from each other, to form a matrix, is stacked on the semi-insulating layer 6.

In this case, the electrodes constituting the first and second electrode layers 4 and 8 are preferably strip-type electrodes. Any electrodes, typically used in the art, can be used as the electrodes of the first and second electrode layers 4 and 8.

In the meantime, the surface layer 10 is formed on the second electrode layer 8 with a certain thickness. If necessary, the electrode ring 12 coming into contact with the target to be recognized can be further formed on one part of the top surface layer 10. In this case, for the electrode ring 12, any materials coming into contact with the target to be recognized, such as a fingerprint, and supplying a current thereto, can be used. The electrode ring 12 has no restriction in shape as long as the shape of the electrode ring 12 ensures effective contact with the target. Preferably, the electrode ring 12 can be formed in a rectangle, circle or an oval shape.

In this case, the surface layer 10 is a contact surface with which the target to be recognized, such as a fingerprint, directly comes into contact. For the surface layer 10, there can be used any materials having excellent physical characteristics, such as abrasion resistance required to provide surface protection and reliability, and water repellency required to obtain an excellent image from a moist target to be recognized such as the fingerprint of a sweaty finger. Preferably, fluoropolymer-based materials can be used for the surface layer 10.

In the meantime, the power supply unit 14 is connected to the electrodes of the first and second electrode layers 4 and 8 to supply a Direct Current (DC) or Alternating Current (AC), if necessary, a DC or AC voltage, to the first and second electrode layers 4 and 8. As an example of the implementation of the power supply unit 14, the power supply unit 14 can be connected to the electrode ring 12 placed on the surface layer 10, instead of the above second electrode layer 8, and used in this state.

In this case, the construction of the electrodes of the second electrode layer 8 or the electrode ring 12, and the electrodes of the first electrode layer 4, which are connected to the power supply unit 14, can be selected in consideration of the purpose, design, manufacturing costs or performance of the fingerprint recognition apparatus. The electrodes of the first and second electrode layers 4 and 8, connected to the power supply unit 14, can be constructed individually to be supplied with a current from the power supply unit 14 or the electrodes of the first or second electrode layer can be constructed integrally to be supplied with a current.

The fingerprint recognition apparatus of the present invention measures currents generated at the intersecting points of the first and second electrode layers 4 and 8 forming a matrix, due to an electric field generated between a contact surface coming into contact with the target to be recognized and the electrodes of the first electrode layer 4, thus reproducing the image of the recognized target. In order to measure the currents generated at the intersecting points of the matrix, the detecting units 16 capable of measuring signals output from the electrodes of the first and second electrode layers 4 and 8, for example, currents, are provided, and the image reproducing unit 18 capable of receiving the output signals measured by the detecting units 16 to reproduce an image is provided.

Hereinafter the operation of the above fingerprint recognition apparatus of the present invention is described in detail.

First, a current is supplied to the power supply unit 14 connected to the electrodes of the first and second electrode layers 4 and 8, and then supplied to the electrodes of the first and second electrode layers 4 and 8. Thereafter, the target to be recognized, such as a fingerprint, is brought into contact with the surface layer 10 of the fingerprint recognition apparatus of the present invention.

If necessary, the power supply unit 14 can be connected to the electrode ring 12 instead of the second electrode layer 8. In this case, if the power supply unit 14 is connected to both the electrode ring 12 and the first electrode layer 4, a part of the target to be recognized is brought into contact with the electrode ring 12 and at the same time with the surface layer 10 of the fingerprint recognition apparatus.

If the target is a fingerprint, an electric field is generated between a ridge 20 of the fingerprint closely coming into contact with the surface layer 10 and the electrodes of the first electrode layer 4.

Next, the impedance of a corresponding portion of the semi-insulating layer 6 is decreased due to the electric field generated between the ridge 20 of the fingerprint and the electrodes of the first electrode layer 4, so that currents flow from the electrodes of the first electrode layer 4 to the electrodes of the second electrode layer 8.

Then, the detecting units 16, connected to the electrodes of the first and second electrode layers 4 and 8, measure signals, such as currents, detected at the electrodes of the first and second electrode layers 4 and 8, and transmit the measured signals to the image reproducing unit 18, so that the intersecting points of the matrix constitute pixels, that can reproduce the recognized target in the form of an image.

In this case, the detecting units 16 can be changed depending on the output signals of the first and second electrode layers 4 and 8. If the output signals are currents, devices capable of measuring currents are used as the detecting units 16, while if the outputs signals are voltages, devices capable of measuring voltages are used as the detecting units 16. However, the current measuring devices are preferably used as the detecting units 16.

Especially, if currents are measured, the amount of current is changed depending on the level of a finger pressure on the surface layer 10, so that there is an advantage in that the detecting units 16 can additionally measure a pressure level.

Hereinafter, a method of reproducing the image of the recognized target on the basis of the first and second electrode layers 4 and 8 and the semi-insulating layer 6 of the fingerprint recognition apparatus is described in detail.

If the impedance of the semi-insulating layer 6 is decreased due to the electric field formed on the semi-insulating layer 6 which is placed below the surface layer 10 coming into contact with the ridge 20 of the fingerprint, the currents having flowed through the electrodes of the first electrode layer 4, flow into the semi-insulating layer 6 with the decreased impedance and the electrodes of the second electrode layer 8 installed next to the semi-insulating layer 6 with the decreased impedance. The currents flowing through the semi-insulating layer 6 and the second electrode layer 8 are measured by the detecting unit 16 connected to a portion of the second electrode layer 8 as output signals. Simultaneously with the measurement of the currents, the currents flowing through the electrodes of the first electrode layer 4 where currents flowing through the semi-insulating layer 6 having the decreased impedance, are measured by the detecting unit 16 connected to the first electrode layer 4.

For example, the detecting units are operated in such a way that, if an electrode of one of the first or second electrode layers 4 or 8 is connected to an addressing controller (performing a function equal to that of a gate controller of an active matrix) as in the case of the scanning operation of a Thin Film Transistor (TFT) sensor, currents corresponding to the respective intersecting points of the electrodes are detected at electrode lines of the other electrode layer (connected to a readout chip).

Through the above method, the image reproducing unit 18 reads the output signals of the first and second electrode layers 4 and 8 forming a matrix below the ridge 20 of the fingerprint, for example, the amount of current and the position information of corresponding electrodes, so that the intersecting points of the first and second electrode layers 4 and 8 constitute pixels, that can reproduce the entire fingerprint image.

As described above, the present invention provides a fingerprint recognition apparatus, which is efficient since it does not require a lens and an image sensor required for conventional optics-type or contact light emitting element-type fingerprint recognition schemes. The present invention is effective since it does not cause the problems of static electricity and mechanical impacts, which may occur in conventional semiconductor-type fingerprint recognition schemes.

Further, the present invention is advantageous in that electrodes are arranged in the form of a matrix and then the intersecting points of the electrodes constitute pixels, which can reproduce a fingerprint image. Therefore, transistors for controlling respective pixels are not necessary, the fingerprint recognition apparatus can be manufactured through a thick film process, such as a screen print, and equipment investment costs for production can be reduced.

Moreover, the present invention is advantageous in that, an entire fingerprint recognition apparatus can be manufactured using a polymer, thus widening a contact area of a fingerprint, obtained from even a dry finger, on a sensor surface. Further, the intensity of a signal is sufficiently high, thus sufficiently reproducing a fingerprint image even though a target to be recognized is dry, and a fingerprint recognition sensor is a thick film sensor, that can reduce an electric field due to static electricity. Moreover, a leakage current is slightly and intentionally generated, thus fundamentally solving a static electricity problem.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A fingerprint recognition sensor, comprising:
a substrate;
a first electrode layer stacked on the substrate and comprised of a plurality of electrodes to allow a current to flow therethrough;
a semi-insulating layer stacked on the first electrode layer to have a certain thickness;
a second electrode layer stacked on the semi-insulating layer and comprised of a plurality of electrodes intersecting the electrodes of the first electrode layer to form a matrix while being spaced apart from each other; and
a surface layer stacked on the second electrode layer with a certain thickness.

2. The fingerprint recognition sensor according to claim 1, wherein the semi-insulating layer is made of a mixture of insulating powder with a polymer binder.

3. The fingerprint recognition sensor according to claim 2, further comprising an electrode ring formed on a portion of a top of the surface layer to come into contact with a target to be recognized.

4. The fingerprint recognition sensor according to claim 1, further comprising an electrode ring formed on a portion of a top of the surface layer to come into contact with a target to be recognized.

5. An apparatus for recognizing a fingerprint, comprising:
(a) the fingerprint recognition sensor having:
a substrate;
a first electrode layer stacked on the substrate and comprised of a plurality of electrodes to allow a current to flow therethrough;
a semi-insulating layer stacked on the first electrode layer to have a certain thickness;
a second electrode layer stacked on the semi-insulating layer and comprised of a plurality of electrodes intersecting the electrodes of the first electrode layer to form a matrix while being spaced apart from each other; and
a surface layer stacked on the second electrode layer with a certain thickness;
(b) a power supply unit connected to the electrodes of the first and second electrode layers of the fingerprint recognition sensor to supply a current thereto;
(c) at least one detecting unit connected to the electrodes of the first and second electrode layers to measure signals output from the electrodes of the first and second electrode layers; and
(d) an image reproducing unit connected to the detecting unit to analyze signal information output from the detecting unit and then reproduce the recognized target in the form of an image.

6. An apparatus for fingerprint recognition according to claim 5 wherein the semi-insulating layer is made of a mixture of insulating powder with a polymer binder.

7. An apparatus for fingerprint recognition according to claim 6 further comprising an electrode ring formed on a portion of a top of the surface layer to come into contact with a target to be recognized.

8. An apparatus for fingerprint recognition according to claim 5 further comprising an electrode ring formed on a portion of a top of the surface layer to come into contact with a target to be recognized.

9. An apparatus for fingerprint recognition, comprising:
(a) the fingerprint recognition sensor having:
a substrate;
a first electrode layer stacked on the substrate and comprised of a plurality of electrodes to allow a current to flow therethrough;
a semi-insulating layer stacked on the first electrode layer to have a certain thickness;
a second electrode layer stacked on the semi-insulating layer and comprised of a plurality of electrodes intersecting the electrodes of the first electrode layer to form a matrix while being spaced apart from each other;
a surface layer stacked on the second electrode layer with a certain thickness; and
an electrode ring formed on a portion of a top of the surface layer to come into contact with a target to be recognized;
(b) a power supply unit connected to both the electrode ring and the electrodes of the first electrode layer of the fingerprint recognition sensor to supply a current thereto;
(c) at least one detecting unit connected to the electrodes of the first and second electrode layers to measure output signals from the electrodes of the first and second electrode layers; and
(d) an image reproducing unit connected to the detecting unit to analyze signal information output from the detecting unit and then reproduce the recognized target in the form of an image.

10. An apparatus for fingerprint recognition according to claim 9 wherein the semi-insulating layer is made of a mixture of insulating powder with a polymer binder.
